(19) United States
(12) Patent Application Publication
(10) Pub. No.: US 2012/0080219 A1
(43) Pub. Date: Apr. 5, 2012

(54) METHOD OF MANUFACTURING ELECTRONIC DEVICE AND ELECTRONIC DEVICE

(75) Inventors: Shuichi TAKEUCHI, Kawasaki (JP); Kenji KOBAE, Kawasaki (JP); Yoshiyuki SATOH, Kawasaki (JP); Naoki ISHIKAWA, Kawasaki (JP); Takeshi MIYAKOSHI, Kawasaki (JP); Tetsuya TAKAHASHI, Kawasaki (JP)

(73) Assignee: FUJITSU LIMITED, Kawasaki-shi (JP)

(21) Appl. No.: 13/208,380

(22) Filed: Aug. 12, 2011

(30) Foreign Application Priority Data
Sep. 30, 2010 (JP) 2010-222928

(51) Int. Cl. H05K 1/02; H05K 3/30

(52) U.S. Cl. 174/259; 29/832

(57) ABSTRACT

A method of manufacturing an electronic device in which an electronic component is flip-chip mounted on a circuit board, the method includes supplying, on an electrode of the circuit board or a terminal of the electronic component, a first resin material of a thickness smaller than a gap between the circuit board and the electronic component, after supplying the first resin material, connecting the terminal to the electrode by melting a solder material disposed on the electrode or the terminal at a first temperature with keeping the terminal in contact with the electrode, after connecting the terminal to the electrode, filling the gap between the circuit board and the electronic component with a second resin material, and heating the second resin material at a second temperature lower than the first temperature.

### CROSS-REFERENCE TO RELATED APPLICATION

This application is based upon and claims the benefit of priority of the prior Japanese Patent Application No. 2010-222928, filed on Sep. 30, 2010, the entire contents of which are incorporated herein by reference.

### FIELD

The embodiment discussed herein is related to a method of manufacturing an electronic device in which an underfill material fills the gap between an electronic component and a circuit board, and to an electronic device.

### BACKGROUND

In response to the requirements for more compact, thinner and higher density electronic devices, an electronic component (for example, a semiconductor chip) and a circuit board may be electrically connected to each other via protruding bumps provided either of the electronic component or the circuit board. Such a connecting method is called flip chip mounting.

The flip chip mounting, however, has the following deficiency; since the electronic component and the circuit board are connected directly with the bumps, the connecting portions with the bumps are sometimes subject to large load due to difference in the coefficient of thermal expansion between the electronic component and the circuit board when the electric device is heated. To avoid this phenomenon, an underfill material may be used to fill the gap between the electronic component and the circuit board to reduce the stress produced in the connecting portions with the bumps.

For example, the gap may be filled with the underfill material in the following manner; the electronic component is flip-chip mounted on the circuit board, and then the fluidal underfill material is supplied to the gap between the electronic component and the circuit board. In this method, however, the electronic component and the circuit board are connected only at the connecting portions with the bumps until the underfill material is cured. Thus, there is a possibility that the electronic component is separated from the circuit board before the underfill material is cured under some connection strength of the connecting portions with the bumps. It is therefore proposed to reinforce the connection between the electronic component and the circuit board by filling the gap between the electronic component and the circuit board with an uncured adhesive and curing the adhesive (see, for example, Japanese Laid-open Patent Publication Nos. 2002-198384 and 2000-315698).

The uncured adhesive contains volatile materials. This means that the adhesive emits a large amount of gas when the electronic component and the circuit board are heated. If the emitted gas is not completely exhausted out of the adhesive, voids will be formed in the adhesive to reduce reliability of the electronic device.

### SUMMARY

According to an aspect of the invention, a method of manufacturing an electronic device in which an electronic component is flip-chip mounted on a circuit board, the method includes supplying, on an electrode of the circuit board or a terminal of the electronic component, a first resin material of a thickness smaller than a gap between the circuit board and the electronic component, after supplying the first resin material, connecting the terminal to the electrode by melting a solder material disposed on the electrode or the terminal at a first temperature with keeping the terminal in contact with the electrode, after connecting the terminal to the electrode, filling the gap between the circuit board and the electronic component with a second resin material, and heating the second resin material at a second temperature lower than the first temperature.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a semiconductor device according to a first embodiment;

FIG. 2 is a sectional view of the semiconductor device according to the first embodiment;

FIG. 3 is a plan view of a circuit board according to the first embodiment;

FIG. 4 is a fragmentary sectional view of the circuit board according to the first embodiment;

FIG. 5 is a side view of a semiconductor chip according to the first embodiment;

FIG. 6 is a bottom view of the semiconductor chip according to the first embodiment;

FIGS. 7A to 7E are explanatory views of a method of manufacturing the semiconductor device according to the first embodiment;

FIG. 8 is a sectional view of a semiconductor device according to a modification of the first embodiment; and

FIG. 9 is an explanatory view of a method of manufacturing a semiconductor device according to the second embodiment.

### DESCRIPTION OF EMBODIMENTS

### First Embodiment

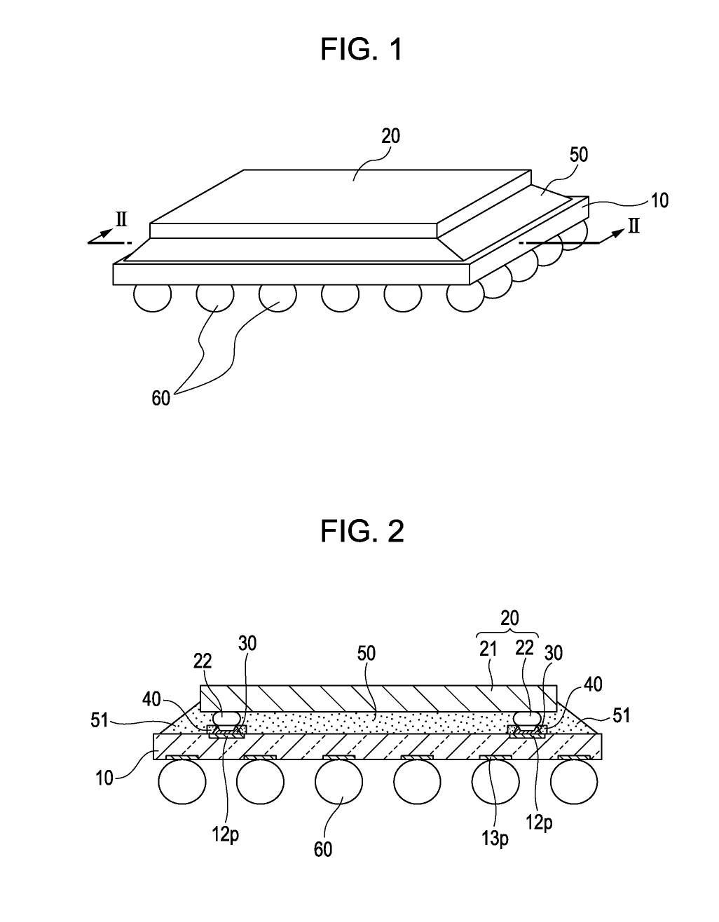

Hereinafter, a first embodiment will be described with reference to FIGS. 1 to 8.

Structure of Semiconductor Device

FIG. 1 is a perspective view of a semiconductor device according to the first embodiment. FIG. 2 is a sectional view of the semiconductor device according to the first embodiment taken along section II-II of FIG. 1.

As illustrated in FIG. 1 or 2, the semiconductor device is a ball grid array (BGA) semiconductor package which includes: a circuit board 10; a semiconductor chip 20 flip-chip mounted on the circuit board 10; a solder material 30 which connects first electrode pads 12p of the circuit board 10 to bumps 22 of the semiconductor chip 20; an adhesive 40 which reinforces connecting portions of the first electrode pads 12p and the bumps 22; underfill resin 50 which fills the gap between the circuit board 10 and the semiconductor chip 20; and solder balls 60 attached to the circuit board 10 as external connection terminals.

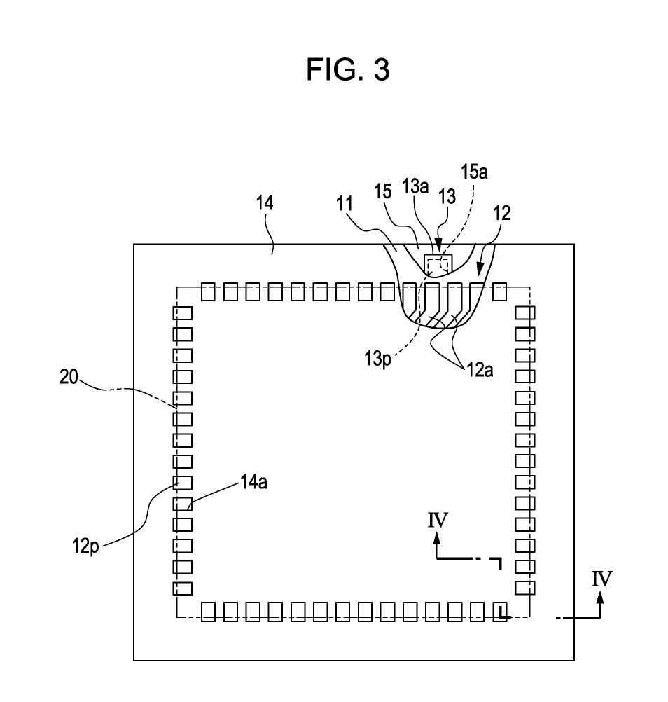

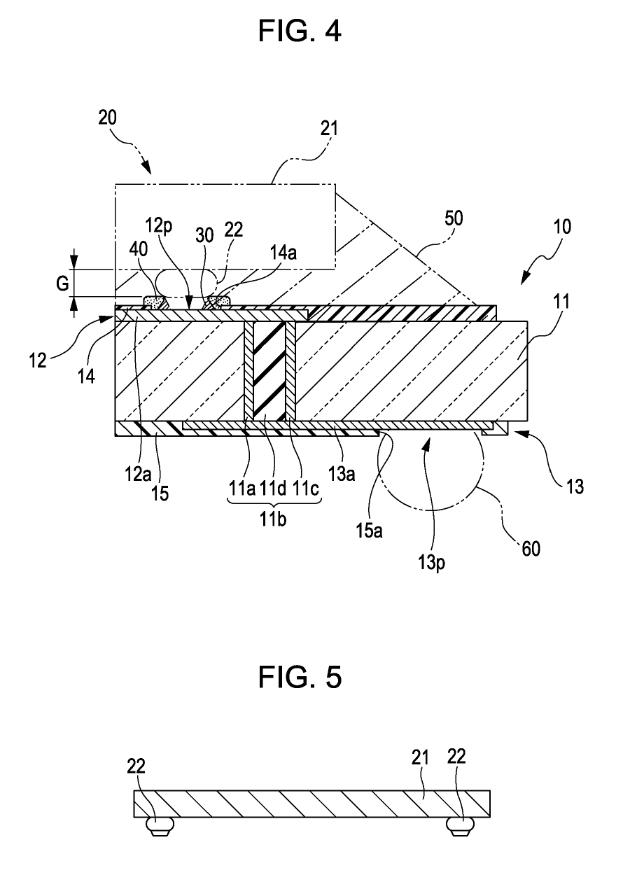

FIG. 3 is a plan view of the circuit board 10 according to the first embodiment. FIG. 4 is a fragmentary sectional view of the circuit board 10 according to the first embodiment taken along section IV-IV of FIG. 3.

The circuit board 10 is a glass epoxy board. The present embodiment, however, is not limited to the same; other printed circuit boards, such as a glass composite board and a ceramic board may also be used.

As illustrated in FIG. 3 or 4, the circuit board 10 is provided with a core material 11, a first wiring layer 12, and second wiring layer 13.

The core material 11 is, for example, a glass cloth impregnated with epoxy resin. The core material 11 has a substantially rectangular shape when seen in a plan view. The thickness of the core material 11 is, for example, 150 to 250 micrometers. The core material 11 includes a plurality of through holes 11a formed at predetermined positions. The through holes 11a penetrate the core material 11 in the vertical direction. A via 11b is embedded in each of the through holes 11a. The via 11b is provided with a conductive film 11c formed on an inner surface of the through hole 11a and an insulation material 1 id filled in the conductive film 11c. The conductive film 11c electrically connects the first wiring layer 12 and the second wiring layer 13. The conductive film 11c is made of, for example, Cu. The insulation material 1 id is made of, for example, epoxy resin or polyimide resin.

The first wiring layer 12 is formed on an upper surface of the core material 11, which is a surface opposite to the semiconductor chip 20. The first wiring layer 12 includes a plurality of first wiring patterns 12a. The first wiring layer 12 may be made of, for example, metallic foil, such as Cu foil. The first wiring layer 12 is formed into patterns of the first wiring patterns 12a by forming, for example, metallic foil, such as Cu foil, on the upper surface of the core material 11 and then removing unnecessary portions of the metallic foil by etching. A first solder resist film 14 is formed on the upper surface of the core material 11. The first solder resist film 14 may be made of, for example, polyimide resin. The first solder resist film 14, which covers the first wiring patterns 12a, includes apertures 14a at positions corresponding to the bumps 22 of the semiconductor chip 20. The first wiring patterns 12a are partially exposed through the apertures 14a of the first solder resist film 14; each of the exposed areas constitutes each of the first electrode pads 12p. Thus, the plurality of first electrode pads 12p are arranged along the periphery of the upper surface of the circuit board 10 at positions corresponding to the bumps 22 of the semiconductor chip 20. The width dimension of each of the first electrode pads 12p is, for example, 10 to 60 micrometers. Similarly, the adjacent first electrode pads 12p are spaced apart by, for example, 10 to 60 micrometers.

The second wiring layer 13 is formed on a lower surface of the core material 11, on which the solder balls 60 are mounted. The second wiring layer 13 includes a plurality of second wiring patterns 13a. The second wiring layer 13 may be made of, for example, metallic foil, such as Cu foil. The second wiring layer 13 is formed into patterns of the second wiring patterns 13a by forming, for example, metallic foil, such as Cu foil, on the lower surface of the core material 11 and then removing unnecessary portions of the metallic foil by etching. A second solder resist film 15 is formed on the lower surface of the core material 11. The second solder resist film 15 may be made of, for example, polyimide resin. The second solder resist film 15 covers the second wiring patterns 13a and a plurality of apertures 15a are formed in a matrix pattern on the entire lower surface of the circuit board 10. The second wiring patterns 13a are partially exposed through the apertures 15a of the second solder resist film 15; each of the exposed areas constitutes each of the second electrode pads 13p. With this, the plurality of second electrode pads 13p are arranged in a matrix pattern on the lower surface of the circuit board 10. Each of the solder balls 60 is mounted on each of the second electrode pads 13p. The solder balls 60 function as external connection terminals when the semiconductor device is mounted on other mounting substrate (i.e., a motherboard).

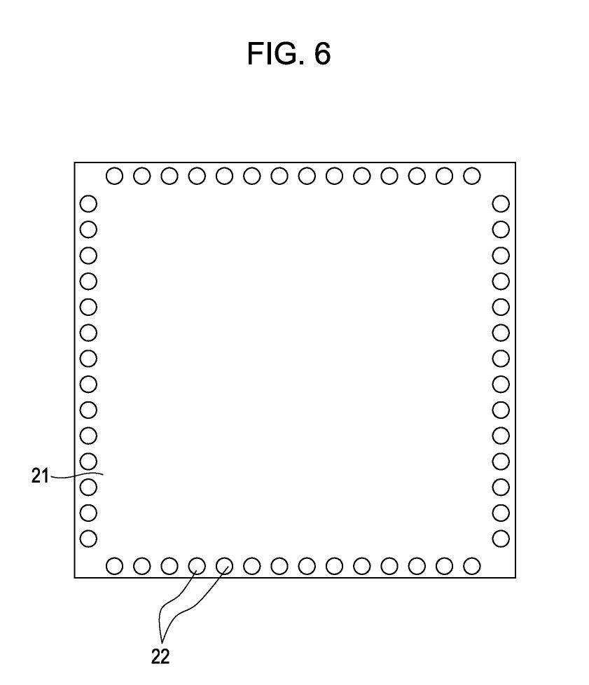

FIG. 5 is a side view of the semiconductor chip 20 according to the first embodiment. FIG. 6 is a bottom view of the semiconductor chip 20 according to the first embodiment. The semiconductor chip 20 is produced in the following manner: for example, a plurality of circuit areas are formed on a semiconductor wafer; and then the semiconductor wafer is diced to individuate the semiconductor chips. The present embodiment, however, is not limited to the semiconductor chip and other electronic components may be used.

As illustrated in FIG. 5 or 6, the semiconductor chip 20 is provided with a chip body 21 and a plurality of bumps 22 which are formed on a lower surface, i.e., a surface opposite to the circuit board 10, of the chip body 21.

The chip body 21 is formed in a substantially rectangular shape when seen in a plan view. The length of each side of the chip body 11 is about 4 mm as a plane dimension. The thickness of the chip body 21 is about 0.2 mm. The present embodiment, however, is not limited to the same; for example, the plane shape of the chip body 21 may be triangular, pentagonal and other polygonal shapes. In addition, the plane shape of the chip body 21 may be circular and elliptical.

The plurality of bumps 22 are arranged along the periphery of the chip body 21. The bumps 22 are spaced at intervals of about 10 to 100 micrometers from each other. The diameter dimension of each of the bumps 22 is, for example, 10 to 60 micrometers. The bumps 22 may be made of, for example, gold. The bumps 22 may be produced by, for example, ball bonding.

The bumps 22 of the semiconductor chip 20 as described above are connected to the first electrode pads 12p of the circuit board 10 via the solder material 30 as illustrated in FIG. 4. The solder material 30 covers the entire surfaces of the first electrode pads 12p and tips of the bumps 22 so as to electrically and mechanically connect the first electrode pads 12p and the bumps 22. The solder material 30 may be made of, for example, lead based solder such as Sn—Pb solder, or non-lead based solder such as Sn—Ag solder and Sn—Zn solder, but are not limited to the same. The gap between the circuit board 10 and the semiconductor chip 20 is defined mainly by the height of the bumps 22, which is about 60 micrometers in the present embodiment.

The adhesive 40 extends from the surface of the first solder resist film 14 to reach peripheral surfaces of the bumps 22 to thereby reinforce the connecting portions of the first electrode pads 12p and the bumps 22. That is, the adhesive 40 covers the solder material 30 from outside to thereby reinforce the solder material 30 itself and, at the same time, the adhesive 40 adheres to both the surface of the first solder resist film 14 and the peripheral surfaces of the bumps 22 to thereby reinforce the connection of the first solder resist film 14 and the bumps 22. The thickness of the adhesive 40 is smaller than the width of the gap between the circuit board 10 and the chip body 21. The thickness of the adhesive 40 according to the present embodiment is about one third of the width of the gap between the circuit board 10 and the chip body 21, i.e., about 20 micrometers. Accordingly, a predetermined gap G is defined between the adhesive 40 and the chip body 21.

The adhesive 40 may be made of, for example, epoxy-based resin. The epoxy-based resin may be, for example, bisphenol epoxy resin to which a curing agent, an additive, a colorant, a filler and the like are added. The curing agent is, for example, acid anhydride. The additive is, for example, a coupling agent. The colorant is, for example, carbon. The filler is, for example, silica. Such epoxy-based resin may be, for example, the “UFR series,” products of Nagase Chemtex Corporation.

Although the adhesive 40 adheres to both the first solder resist film 14 and the bumps 22 in the present embodiment, the present invention is not limited to the same. That is, since the connecting portions of the first electrode pad 12p and the bumps 22 can be reinforced if the adhesive 40 at least covers the solder material 30, it is not necessary for the adhesive 40 to adhere to both the first solder resist film 14 and the bumps 22.

The underfill resin 50 fills the gap between the circuit board 10 and the semiconductor chip 20. The underfill resin 50, of course, also fills the gap G between the adhesive 40 and the chip body 21. The underfill resin 50 adheres to both the circuit board 10 and the semiconductor chip 20 to join the same with the contracting force produced when the material of the underfill resin 50 is cured. The underfill resin 50 protrudes from the periphery of the semiconductor chip 20 and forms a fillet 51. The fillet 51 extends from the upper surface of the circuit board 10 and reaches side surfaces of the semiconductor chip 20 to thereby increase bonding strength between the circuit board 10 and the semiconductor chip 20.

The underfill resin 50 may be made of, for example, epoxy-based resin. The composition of the epoxy-based resin is substantially equivalent to that of the adhesive 40; however, the type and content of the curing agent may be arbitrarily selected so that the epoxy-based resin has longer curing time than the adhesive 40 does. Such epoxy-based resin may be, for example, “U8439-01,” a production of Namics Corporation.

Method of Manufacturing Semiconductor Device

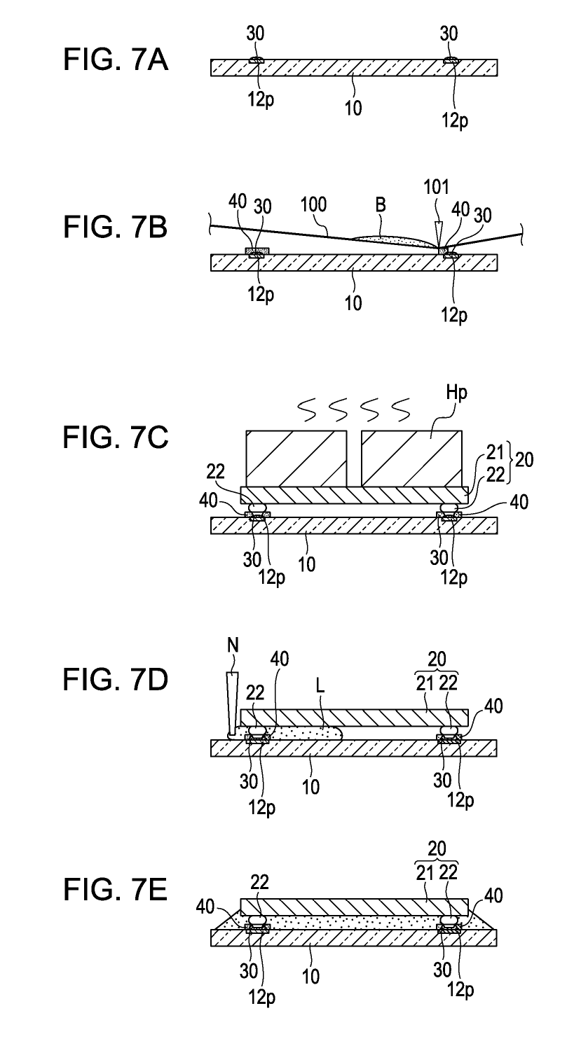

FIGS. 7A to 7E are explanatory views of a method of manufacturing the semiconductor device according to the first embodiment. Note that the configuration of the semiconductor device is not illustrated in detail in FIGS. 7A to 7E; FIGS. 1 to 6 should be referred to if necessary.

First, as illustrated in FIG. 7A, the solder material 30 is applied to the first electrode pads 12p of the circuit board 10. The solder material 30 may be applied by, for example, precoating. Alternatively, a circuit board on which the solder material 30 is already applied to the first electrode pads 12p may be used.

Next, the adhesive 40 which is uncured is selectively applied to the first electrode pads 12p of the circuit board 10 to cover the solder material 30 as illustrated in FIG. 7B. The adhesive 40 is a resin material which has shorter curing time than the underfill resin 50 does. Such a resin material may be, for example, the “UFR series,” a product of Nagase Chemtex Corporation as mentioned above. The adhesive 40 may be applied by, for example, screen printing. If the adhesive 40 is applied by screen printing, a flexible plate 100 made of, for example, SUS is disposed above the circuit board 10 as a screen. The flexible plate 100 includes an opening (not illustrated) at a position corresponding to a print pattern. The shape of the opening corresponds to that of the print pattern. An uncured adhesive B applied to the flexible plate 100 is squeeged using a squeegee 101 to thereby apply the adhesive 40 to the first electrode pads 12p of the circuit board 10 in accordance with the shape of the opening of the flexible plate 100. The opening of the flexible plate 100 according to the present embodiment includes the entire surfaces of the first electrode pads 12p and the entire inner edges of the apertures 14a of the first solder resist film 14. Accordingly, the adhesive 40 is applied to cover a range from the first electrode pads 12p to the first solder resist film 14.

Next, as illustrated in FIG. 7C, a lower surface of the pressure head Hp sucks the semiconductor chip 20 and positions the semiconductor chip 20 such that the bumps 22 correspond to the first electrode pads 12p. The pressure head Hp sucking the semiconductor chip 20 is then moved downward to let the bumps 22 be in contact with the first electrode pads 12p. The adhesive 40 which is applied to the first electrode pads 12p has not been cured at this time is forced out by the bumps 22 during the downward movement of the semiconductor chip 20. Thus, the bumps 22 of the semiconductor chip 20 can be brought into contact with the first electrode pads 12p. The adhesive 40 forced out by the bumps 22 creeps up the peripheral surfaces of the bumps 22 by the surface tension thereof. In this manner, the adhesive 40 extends from the surface of the first solder resist film 14 and reaches the peripheral surfaces of the bumps 22.

Next, a heater (not illustrated) provided in the pressure head Hp is operated to heat the semiconductor chip 20. The heating temperature is equal to or higher than the melting point of the solder material 30. Specifically, the heating temperature is, for example, 200 to 300 degrees and more preferably 230 to 270 degrees depending on the material of the solder material 30. The heating time also depends on the material of the solder material 30 and is, for example, 5 to 15 seconds and more preferably 8 to 12 seconds.

When the semiconductor chip 20 is heated, the solder material 30 melts and spreads across the entire first electrode pads 12p. The solder material 30 then creeps up the peripheral surfaces of the bumps 22. The solder material 30, which is covered with the adhesive 40 at this time, wet-spreads and enters the gap between the adhesive 40 and the first electrode pads 12p and the gap between the adhesive 40 and the bumps 22 by the surface tension thereof. In this manner, the bumps 22 of the semiconductor chip 20 are connected to the first electrode pads 12p of the circuit board 10 electrically and mechanically. That is, the semiconductor chip 20 is flip-chip mounted on the circuit board 10.

When the semiconductor chip 20 is heated, the adhesive 40 is also heated simultaneously. When the adhesive 40 is heated, volatile materials or melted water contained in the adhesive 40 volatilize and evaporate and are exhausted from the surface of the adhesive 40. At this time, the adhesive 40 is not in contact with the chip body 21 of the semiconductor chip 20. Thus, the gas generated inside the adhesive 40 is exhausted not only from the peripheral surface of the adhesive 40 but from an upper surface of the adhesive 40. Accordingly, the gas generated inside the adhesive 40 is rapidly exhausted from the surface of the adhesive 40 and, as a result, formation of voids is prevented. Since the gas generated inside the adhesive 40 is forced out of the adhesive 40 before the adhesive 40 is cured, no gas remains in the cured adhesive 40 and therefore no voids are formed. Since the melting temperature of the solder material 30 is relatively high, a large quantity of gas is generated abruptly inside the adhesive 40 when the solder material 30 melts, the gas is exhausted from the adhesive 40 rapidly as described above and therefore formation of voids in the adhesive 40 can be reduced to the minimum. Since the adhesive 40 is not in contact with the chip body 21 of the semiconductor chip 20, the adhesive 40 does not flow in the gap between the circuit board 10 and the semiconductor chip 20. Therefore, no trapping of air occurs accompanying the flow of the adhesive 40, which also prevents formation of voids in the adhesive 40. When heated, the adhesive 40 is cured to reinforce the connecting portions of the first electrode pads 12p and the bumps 22 as described above.

The circuit board 10 and the semiconductor chip 20 are then transferred to an underfill supply device (not illustrated). At this time, the solder material 30 for connecting the first electrode pads 12p and the bumps 22 is covered with the adhesive 40. Therefore, even if a crack or other problem occurs in the solder material 30, the adhesive 40 disposed over the solder material 30 prevents collapse of the solder material 30. This prevents removal of the semiconductor chip 20 from the circuit board 10 during the transfer of the circuit board 10 and the semiconductor chip 20.

Then, as illustrated in FIG. 7D, uncured underfill resin L is supplied to the circuit board 10 from a nozzle N of the underfill supply device. Here, an end of the nozzle N is situated at a position opposite at least to one side of the semiconductor chip 20. This allows the underfill resin L discharged from the nozzle N to enter the gap between the circuit board 10 and the semiconductor chip 20 by the capillary action. The underfill resin L may be, for example, the “UFR series,” a product of Nagase Chemtex Corporation” mentioned above. The supply amount of the underfill resin L is determined such that the gap between the circuit board 10 and the semiconductor chip 20 is filled completely and the fillet 51 is formed on the periphery of the semiconductor chip 20.

After the gap between the circuit board 10 and the semiconductor chip 20 is filled with the underfill resin L as illustrated in FIG. 7E, the circuit board 10 and the semiconductor chip 20 are transferred to a heating furnace (not illustrated) and heated at the temperature of, for example, 120 to 180 degrees over a period of, for example, one to three hours. This allows the underfill resin 50 to cure and join the circuit board 10 and the semiconductor chip 20 together by the contracting force thereof.

The underfill resin 50 has longer curing time than the adhesive 40 does. In addition, the underfill resin 50 has lower heating temperature than the adhesive 40 does. This means that the underfill resin 50 cures more slowly at a lower temperature over a longer period of time than the adhesive 40 does. The volatile materials or melted water contained in the underfill resin 50 are exhausted completely before the underfill resin 50 is cured, and therefore voids in the underfill resin 50 is less often formed. Since the heating temperature of the underfill resin 50 is lower than the melting point of the solder material 30, the solder material 30 does not melt at the heating temperature of the underfill resin 50.

Next, each of the solder balls 60 is attached to each of the second electrode pads 13p of the circuit board 10. In this manner, the semiconductor device according to the first embodiment as illustrated in FIG. 2 is completed.

As described above, the connecting portions of the first electrode pads 12p and the bumps 22 are covered with the adhesive 40 before the underfill resin 50 fills the gap between the circuit board 10 and the semiconductor chip 20 in the present embodiment. The connecting portions of the first electrode pads 12p and the bumps 22 are reinforced by the adhesive 40. This prevents removal of the semiconductor chip 20 from the circuit board 10 until the underfill resin 50 fills the gap between the circuit board 10 and the semiconductor chip 20.

In addition, the thickness of the adhesive 40 is smaller than the width of the gap between the circuit board 10 and the semiconductor chip 20. This allows that, even if the adhesive 40 is heated under the high temperature to melt the solder material 30, the gas produced in the adhesive 40 is exhausted rapidly and therefore formation of voids in the adhesive 40 is prevented.

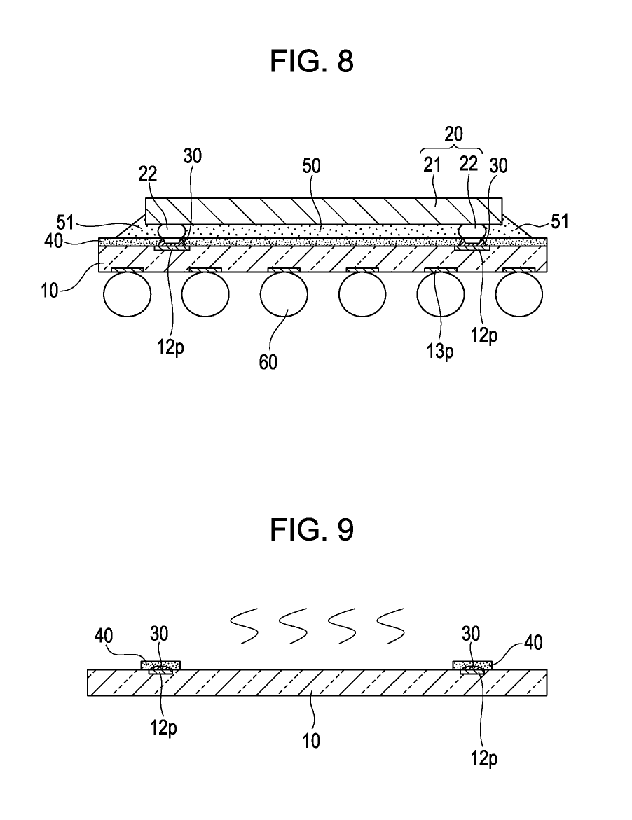

Although the uncured adhesive 40 is selectively applied to the first electrode pads 12p of the circuit board 10 in the present embodiment, the present invention is not limited to the same. For example, as illustrated in FIG. 8, the uncured adhesive 40 may be applied to the entire upper surface of the circuit board 10. If the entire upper surface of the circuit board 10 is covered with the adhesive 40, unevenness on the circuit board 10 is reduced compared with a configuration in which the upper surface of the circuit board 10 is partially covered with the adhesive 40. With this configuration, trapping of air during the supply of the uncured underfill resin 50 less often occurs. Thus formation of voids in the gap between the circuit board 10 and the semiconductor chip 20 can be further reduced.

Although the uncured adhesive 40 is applied to the first electrode pads 12p of the circuit board 10 in the present embodiment, the present invention is not limited to the same. For example, the uncured adhesive 40 may be applied to the bumps 22 of the semiconductor chip 20. The adhesive 40 may be applied to the bumps 22 by, for example, dipping.

### Second Embodiment

Hereinafter, a second embodiment will be described with reference to FIG. 9. Components similar to those of the first embodiment will not be described.

Method of Manufacturing Semiconductor Device

FIG. 9 is an explanatory view of a method of manufacturing a semiconductor device according to the second embodiment.

In the method of manufacturing a semiconductor device according to the second embodiment, B-stage resin is used as an adhesive 40. In the method of manufacturing a semiconductor device according to the second embodiment, the adhesive 40 is heated to enter B-stage as illustrated in FIG. 9 between the application of the adhesive 40 to the circuit board 10 and the flip chip mounting of the semiconductor chip 20 on the circuit board 10. The heating temperature herein is, for example, 150 to 180 degrees.

The B-stage adhesive 40 is heated to enter C-stage, i.e., is completely cured during the heating for the flip chip mounting of the semiconductor chip 20 on the circuit board 10. The B-stage adhesive 40 is temporarily fluidized during the heating for the flip chip mounting before heated to enter C-stage. This allows the gas generated inside the adhesive 40 to be rapidly exhausted from the adhesive 40. Further, since the adhesive 40 is temporarily fluidized, the solder material 30 can flow, or wet-spread, without any interference during the flip chip mounting of the semiconductor chip 20 on the circuit board 10.

Since the adhesive 40 is heated to enter B-stage after being applied to the circuit board 10 as in the present embodiment, any outflow of the adhesive 40 from the desired position during the flip chip mounting of the semiconductor chip 20 on the circuit board 10 can be prevented. Especially if the uncured adhesive 40 is applied to the entire upper surface of the circuit board 10, considerable attention should be paid for the outflow of the adhesive 40; however, unnecessary outflow of the adhesive 40 can be prevented very easily by heating the adhesive 40 to be gelled.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A method of manufacturing an electronic device in which an electronic component is flip-chip mounted on a circuit board, the method comprising:
supplying, on an electrode of the circuit board or a terminal of the electronic component, a first resin material of a thickness smaller than a gap between the circuit board and the electronic component;
after supplying the first resin material, connecting the terminal to the electrode by melting a solder material disposed on the electrode or the terminal at a first temperature with keeping the terminal in contact with the electrode;
after connecting the terminal to the electrode, filling the gap between the circuit board and the electronic component with a second resin material; and
heating the second resin material at a second temperature lower than the first temperature.

2. The method of manufacturing an electronic device according to claim 1, wherein the first resin material is cured upon melting the solder material.

3. The method of manufacturing an electronic device according to claim 1, wherein B-stage resin is used as the first resin material, the method further comprising heating the first resin material to enter B-stage before connecting the terminal to the electrode.

4. The method of manufacturing an electronic device according to claim 1, wherein the first resin material is selectively supplied to the electrode by screen printing.

5. The method of manufacturing an electronic device according to claim 1, wherein the first resin material is supplied to an entire portion on a surface of the circuit board, the portion being facing the electronic component.

6. The method of manufacturing an electronic device according to claim 1, wherein the second resin material is supplied to the gap between the circuit board and the electronic component by capillary action.

7. An electronic device comprising:
a circuit board including an electrode;
an electronic component provided above the circuit board and including a terminal on a surface of the electronic component, the surface facing the circuit board;
a solder material connecting the electrode and the terminal;
a first resin material provided on the solder material and has a thickness smaller than a gap between the circuit board and the electronic component; and
a second resin material filling the gap between the circuit board and the electronic component.

8. The electronic device according to claim 7, wherein the first resin material is selectively provided on the electrode.

9. The electronic device according to claim 7, wherein the first resin material is supplied to an entire portion on a surface of the circuit board, the portion being facing the electronic component.

10. The electronic device according to claim 7, wherein the first resin material mechanically connecting the circuit board and the terminal.
